(19) United States
(12) Patent Application Publication
(10) Pub. No.: US 2012/0261526 A1
(43) Pub. Date: Oct. 18, 2012

(54) FRAME-LIKE HOLDER FOR A SOLAR PANEL, WITH A CABLE HOLDER

(75) Inventor: Greg Rentfrow, Tucson, AZ (US)

(73) Assignee: SOLON CORPORATION, Tucson, AZ (US)

(21) Appl. No.: 13/085,505

(22) Filed: Apr. 13, 2011

(51) Int. Cl. H01L 23/13; F16L 3/08; F16L 3/22

(52) U.S. Cl. 248/68.1; 248/65; 248/74.2

(57) ABSTRACT

A frame-like holder for a solar panel includes a substantially L-shaped profile having at least one first leg that is orthogonal relative to the solar panel in an installed position of the solar panel and at least one second leg that adjoins the at least one first leg at an end of the at least one second leg that faces away from the solar panel. A cable holder is integrated into a front face of the at least one second leg of the L-shaped profile, the cable holder including a groove extending along the front face and being configured to receive and secure the at least one electric cable.

### FIELD

The present invention relates to a frame-like holder for a solar panel.

### BACKGROUND

Solar panels hold the solar cells used to directly generate electric energy and they constitute the core of a solar module. Solar panels can be flexibly laminated in place or else applied rigidly onto glass cover panes. They are joined to a substrate, usually a pitched roof or a flat roof, by means of a frame-like holder that is either arranged under the solar panels (formation of a solar module without a frame) or else wraps around the edge of the solar panel (formation of a solar module with a frame). The solar module is brought to the installation site in its completely assembled state and is mounted onto the substrate. All solar modules have electric cables with which they are connected to each other and ultimately to a current-collecting device such as, for example, a transformer or a battery. During the installation, the free electric cables can be a source of hindrance or even of danger for the technicians. Broken electric cables are laborious to repair. Even after the installation, electric cables on the substrate can be a source of hindrance. For this reason, the state of the art provides cable holders that affix and secure the electric cables on the frame-like holder of the solar module.

U.S. Pat. No. 7,406,800 B2 describes a framed solar panel in which cables run between the individual frames through grooves that are located in the front wall of the frame profile but that do not extend along the profile, but rather, run orthogonally to it (see FIG. 2A). Therefore, the cable holders should be construed as cable bushings between the individual solar panels and they do not serve to hold the cables of the individual solar panel. German laid-open document DE 102005 032 716 A1 discloses positioning the electric cable on the underside of the frame of a solar panel in a trough-like groove and affixing it with a protective film (see FIG. 4). The groove is not arranged in the area of the front face and does not serve to hold the electric cable either.

German utility model 20 2008 009 758 U1, in FIG. 2, shows a frame-like holder for a solar panel consisting of a basically L-shaped profile with at least one leg that is orthogonal relative to the solar panel and at least one parallel leg, whereby the parallel leg adjoins the orthogonal leg at its end facing away from the solar panel. A cable holder consists of a curved clamp that extends over the front face of the parallel leg and latches on the underside of the leg into a groove in the area of the orthogonal leg. On the inside of the parallel leg, the clamp has a straight strut to which or behind which the electric cable can be affixed; other embodiments for affixing the electric cable are not put forward. On the side of the orthogonal leg facing the solar panel, there are two additional parallel legs that wrap around the edge of the solar panel, so that a framed solar module is formed. On the inner corners of each parallel leg, the holder has a groove-like channel that extends along the profile. These channels, however, do not serve to hold electric cables, but rather, receive screws used for the orthogonal corner connection of two profiles. These are so-called screw channels that secure the screws by means of deformation.

Such screw channels are also described in European patent application EP 1 146 297 A1 (see FIG. 3 for a frameless solar module) and in U.S. Pat. Appln. 2009/0194098 A1 (see FIG. 6 for a framed solar module). Here, too, the screw channels serve to receive screws used to create a corner connection. Special cable holders are not provided for the frame-like holders in these two publications.

Japanese laid-open document JP 11062143 A likewise describes a frame with groove-shaped channels. This frame, however, serves to concurrently hold two solar panels and can be deformed to a certain extent by the grooves. Once the solar panels have been put in place, a fixation piece is centrally pressed in, which then latches into guide grooves. The deformation of the grooves underneath generates a restoring force when the fixation piece is pressed in, thus affixing the fixation piece and the two solar panels.

### SUMMARY

In an embodiment, the present invention provides a frame-like holder for a solar panel including a substantially L-shaped profile having at least one first leg that is orthogonal relative to the solar panel in an installed position of the solar panel and at least one second leg that adjoins the at least one first leg at an end of the at least one second leg that faces away from the solar panel. A cable holder is integrated into a front face of the at least one second leg of the L-shaped profile, the cable holder including a groove extending along the front face and being configured to receive and secure the at least one electric cable.

### BRIEF DESCRIPTION OF THE DRAWINGS

Exemplary embodiments of the frame-like holder according to the present invention will be explained in greater detail below for purposes of elucidating the invention. The invention is not limited to the exemplary embodiments. Other features and advantages of various embodiments of the present invention will become apparent by reading the following detailed description with reference to the attached drawings which illustrate the following:

FIG. 1 shows a perspective view of a frame-like holder with a solar panel;

FIG. 2 shows a cross section through a first L-shaped profile;

FIG. 3 shows a sectional view of a cross section through a second L-shaped profile; and

FIG. 4 shows a perspective view of various latching elements.

### DETAILED DESCRIPTION

An aspect of the present invention provides a frame-like holder for a solar panel in which electric cables can be held in a simple and yet reliable manner.

In an embodiment, the present invention includes a basically L-shaped profile with at least one leg that is orthogonal relative to the solar panel and with at least one parallel leg that adjoins the orthogonal leg at its end facing away from the solar panel, and with a cable holder on the front face of the parallel leg for purposes of holding at least one electric cable.

In the frame-like holder according to an embodiment of the present invention, the cable holder is integrated into the front face of the parallel leg of the L-shaped profile and consists of a groove that runs along the front face into which the electric cable can be inserted and secured. As a result, the electric cable runs along the frame-like holder. The holder according to an embodiment of the present invention reliably prevents cables from dangling freely or from straddling the frame during the storage and transportation of the solar module as well as during and after the installation. In the groove, the electric cable is reliably protected against damage. Here, the groove can be present either in sections or continuously in the front face of the parallel leg of the L-shaped profile. The electric cable is secured, even when the groove is present in sections. The groove is appropriately interrupted in the area of other structural elements such as, for example, supports for the frame-like holder on the substrate, since in these areas, it is at times difficult to insert the electric cable. The cable is secured especially reliably when the groove is configured to be continuous and the electric cable is inserted into the groove along the greatest possible distances. Also in the case of a continuous groove, there can be segments in inaccessible places into which the electric cable cannot be inserted.

In an embodiment, the inserted electric cable is held in place, or clamped in the groove, essentially by means of simple frictional contact. For this purpose, it is advantageous for the groove to have a rounded cross section. The depth of the groove can be configured as a function of the design of the L-shaped profile. In particular, the groove can be configured to be of such a depth that only one cable can be inserted into it. However, it is also possible to employ a deeper groove into which, for example, two electric cables can be inserted, one on top of the other. In order to ensure a secure clamping of both electric cables, it is advantageous for the cross section of the groove to be rounded in the form of a figure eight. If the front face of the parallel leg is sufficiently wide, it is, of course, possible to insert two or more electric cables into appropriate grooves along the height of the front face.

It is likewise advantageous for the electric cable to be securely installed in the corners. The electric cable cannot be installed completely in sharp corners since it would then kink. Fundamentally speaking, the electric cable can be freely pulled through the corner from the groove in the parallel leg of one L-shaped profile over to the groove in the parallel leg of the other L-shaped profile. For this purpose, appropriate lateral cutouts must be provided in the grooves. However, a corner piece can be arranged between the grooves for each corner, and it likewise has a groove and also securely holds and guides the electric cable through the corner. In this context, the corner pieces are particularly easy to provide if the frame-like holder is configured so as to be rectangular and to have right-angled inside corners.

The frame-like holder of the invention is based on an L-shaped profile. In other words, the basic structure of the profile is shaped like an “L” with one leg positioned orthogonally to the solar panel and with another leg positioned in parallel and being shorter than the orthogonal leg. Here, the one parallel leg is located at the end of the orthogonal leg facing away from the solar panel and it serves to support the solar panel on the substrate and not to support the solar panel in the frame-like holder. For this purpose, preferably another parallel leg of the L-shaped profile can be provided which adjoins the orthogonal leg at its end facing the solar panel and which can be attached under the edge area of the solar panel. This configuration gives rise to a so-called “frameless” holder for the solar panel in which the profile runs underneath the solar panel and consequently is not visible from above. This prevents dirty edges on the solar panel, in addition to which it gives the installed solar panels a smooth overall appearance. However, it is also possible to provide two additional parallel legs on the L-shaped profile which adjoin the orthogonal leg at its end facing the solar panel and which surround the edge area of the solar panel in a U-shaped manner. This creates a frame for the solar panel that is very secure and that also protects the solar panel along its peripheral side edge. The support function of the solar panel on the substrate is taken over by the orthogonal leg of the L-shaped profile. In order to improve the stability of the profile, preferably another orthogonal leg can be provided that runs parallel to the first parallel leg. Other embodiments of the L-shaped profile, for instance, additional steps or bores can be easily created, for example, out of aluminum, by means of the continuous casting method, for which purpose reference is hereby made to the embodiments.

In one embodiment, the electric cables are already held in place in the groove exclusively due to friction. In order to secure them additionally, for instance, also when tensile forces are exerted on the electric cable, it is advantageous to provide simple clips or other latching elements, for instance, simple bolts, for purposes of securing the electric cable in the groove, whereby these clips can be simply clipped onto the groove or else flipped or slid over it. Moreover, advantageously and preferably, the L-shaped profile can be fastened to the substrate by means of a screw that passes through a bore into a cutout of the L-shaped profile. In order to distribute the force of the screw head, a washer is also placed into the cutout. Additional information can be gleaned from the embodiments that follow.

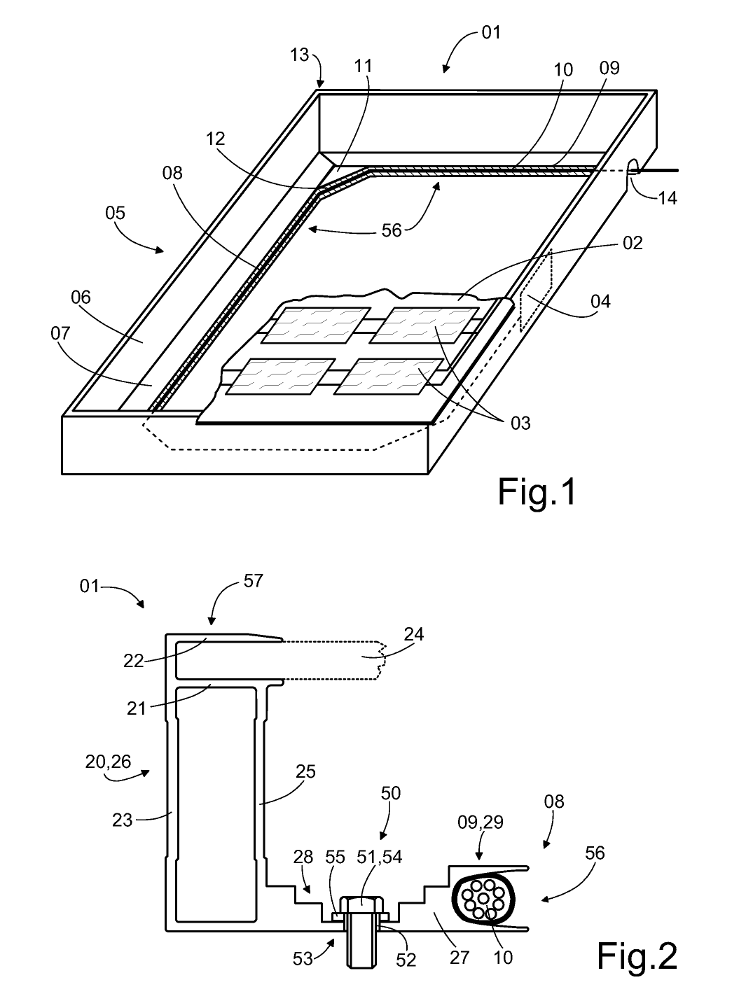

FIG. 1 shows a perspective sectional view of a rectangular frame-like holder 01 for a solar panel 02 having solar cells 03 that are interconnected in a junction box 04. The frame-like holder 01 consists of a basically L-shaped profile 05 with at least one leg 06 that is orthogonal relative to the solar panel 02 and with at least one leg 07 that is parallel relative to the solar panel 02. Here, one end of the orthogonal leg 06 adjoins underneath the solar panel 02 so that the latter appears to be frameless when seen from above. The parallel leg 07 adjoins the end of the orthogonal leg 06 facing away from the solar panel 02. A cable holder 08 in the form of a longitudinal groove 09 is integrated into a front face 56 of the parallel leg 07 and, in the embodiment shown, an electric cable 10 is inserted and held in place in said groove 09.

FIG. 1 also shows a corner piece 11 with a corner groove 12 that connects the adjacent grooves 09, whereby the electric cable 10 runs through the rectangular inner corner 13 in said corner groove 12. In the embodiment shown, the electric cable 10, starting at the junction box 04, runs through almost the entire inner area of the frame-like holder 01 into the grooves 09, 12 and then, via a bushing 14, leaves the frame-like holder 01 in order to run to the adjacent frame-like holder or to another functional element, for instance, a rectifier or a converter or else a battery. The figure shows the electric cable 10 running continuously in the groove 09, demonstrating that the electric cable 10 cannot hang freely and does not pose any danger.

FIG. 2 shows the cross section of another, basically L-shaped profile 20 having two additional parallel legs 21, 22 which adjoin the orthogonal leg 23 at its end facing the solar panel 24 and which surround the edge area 57 of the solar panel 24 in a U-shaped manner. From a top view, the solar panel 24 thus appears to be framed. Furthermore, the L-shaped profile 20 still has another orthogonal leg 25 that runs parallel to the first orthogonal leg 23 and that mechanically strengthens the L-shaped profile 20 in the manner of a hollow profile. This is particularly advantageous if the L-shaped profile 20 is a simple aluminum profile 26 made by means of a continuous casting method. In order to avoid notching forces and also for reinforcement purposes, the parallel leg 27 of the L-shaped profile 20 also has steps 28. The figure also shows a groove 29 with a rounded cross section into which the electric cable 10 is clamped.

FIG. 2 shows a detailed view of a fastener 50 of the L-shaped profile 20 on the substrate using screws 51 that pass through bores 52 into an elongated, rectangular cutout 53 of the L-shaped profile 20. In order to distribute the force of the screw heads 54, washers 55 are inserted into the cutout 53.

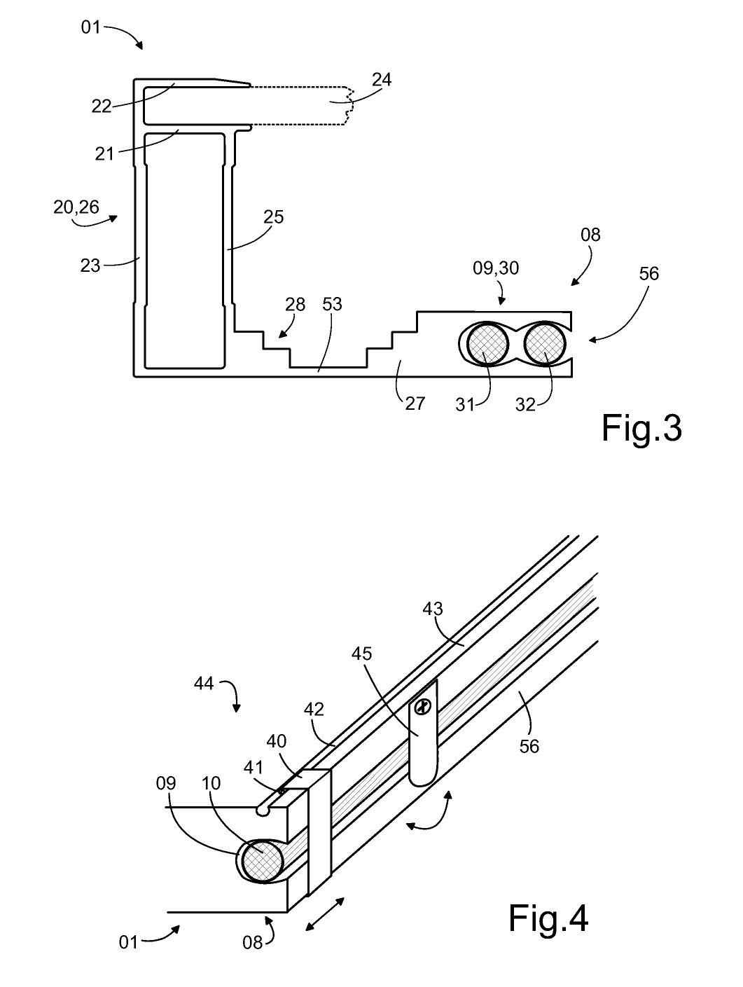

FIG. 3 corresponds to FIG. 2, except that it shows a sectional view of a double groove 30 with a double rounded cross section in the form of a figure eight, whereby two electric cables 31, 32 can be inserted one after the other into said groove 30. The figure depicts an embodiment in which the two electric cables 31, 32 are arranged next to each other. Depending on the width of the front face 56, the two electric cables 31, 32 can, of course, also be arranged one on top of the other. As a function of the configuration of the parallel leg 27 of the L-shaped profile 20, it is also possible for more than two electric cables 31, 32 to be inserted and held in the cable holder 08.

As a rule, the electric cable 10 already stays in the groove 09 due to frictional contact. FIG. 4 shows a perspective view of a clip 40 whose thickened segments are clipped into small grooves 42 of the parallel leg 43 of the L-shaped profile 44 and, as an alternative, an additional latching element 45, here in the form of a simple rotatable tab 46, for purposes of securely retaining the electric cable 10 in the groove 09 even, for example, under tensile load.

Reference numerals that are not shown in a given figure can be seen in the other figures. The embodiments of the invention shown are to be considered as examples. Other embodiments of the invention are likewise possible.

While the invention has been particularly shown and described with reference to preferred embodiments thereof, it will be understood by those skilled in the art that various changes in form and details may be made therein without departing from the spirit and scope of the invention.

### LIST OF REFERENCE NUMERALS

01 frame-like holder
02 solar panel
03 solar cell
04 junction box
05 L-shaped profile
06 orthogonal leg
07 parallel leg
08 cable holder
09 groove
10 electric cable
11 corner piece
12 corner groove
13 inner corner
14 bushing
20 L-shaped profile
21 first additional parallel leg
22 second additional parallel leg
23 orthogonal leg
24 solar panel
25 additional parallel orthogonal leg
26 aluminum profile
27 parallel leg
28 step
29 groove with rounded cross section
30 double groove
31 first electric cable
32 second electric cable
40 clip
41 thickened segment
42 small groove
43 parallel leg
44 L-shaped profile
45 additional latching element
50 fastener
51 screw
52 bore
53 cutout
54 screw head
55 washer
56 front face of 07, 27
57 edge area of 02, 24

What is claimed is:

1. A frame-like holder for a solar panel comprising:
a substantially L-shaped profile including at least one first leg that is orthogonal relative to the solar panel in an installed position of the solar panel and at least one second leg that adjoins the at least one first leg at an end of the at least one second leg that faces away from the solar panel; and
a cable holder integrated into a front face of the at least one second leg of the L-shaped profile, the cable holder including a groove extending along the front face and being configured to receive and secure the at least one electric cable.

2. The frame-like holder according to claim 1, wherein the groove is disposed in sections along the front face of the at least one second leg.

3. The frame-like holder according to claim 1, wherein the groove is disposed continuously along the front face of the at least one second leg.

4. The frame-like holder according to claim 1, wherein the groove includes one rounded cross-sectional region configured to receive the at least one electric cable and hold it therein.

5. The frame-like holder according to claim 1, wherein the at least one electric cable includes a first and a second electric cable, and wherein the groove includes two rounded cross-sectional regions configured as a figure eight so as to form a double groove, the double groove being configured to respectively receive the first and second electric cables and hold them therein.

6. The frame-like holder according to claim 1, wherein the frame-like holder has a rectangular configuration and includes a corner piece in each right-angled inside corner, the corner piece including a corner groove configured to adjoin adjacent grooves in the front face of the at least one second leg of the L-shaped profile.

7. The frame-like holder according to claim 1, wherein the at least one second leg includes a first parallel leg and a second parallel leg, the first parallel leg adjoining the at least one first leg at the end that faces away from the solar panel, the second parallel leg adjoining the at least first leg at an opposite end thereof facing the solar panel, the second parallel leg being configured for attachment below an edge area of the solar panel.

8. The frame-like holder according to claim 1, wherein the at least one parallel leg includes a first, a second and a third parallel leg, the first parallel leg adjoining the at least one first leg at the end that faces away from the solar panel, the second and third parallel legs adjoining the at least first leg at an opposite end thereof facing the solar panel, the second and third parallel legs forming a U-shaped recess configured to surround an edge area of the solar panel.

9. The frame-like holder according to claim 1, wherein the at least one first leg includes a first orthogonal leg and a second orthogonal leg that extend parallel to each other.

10. The frame-like holder according to claim 1, further comprising at least one of a clip and a latching element configured to retain the at least one electric cable in the groove.

11. The frame-like holder according to claim 1, wherein the L-shaped profile is formed from a continuously-cast aluminum profile.

12. The frame-like holder according to claim 1, wherein the L-shaped profile includes a cutout configured for at least one of a screw and a washer so as to provide for attachment of the L-shaped profile.
